(19) United States
(12) Patent Application Publication
(10) Pub. No.: US 2018/0122655 A1
(43) Pub. Date: May 3, 2018

(54) ENDPOINT GAS LINE FILTER FOR SUBSTRATE PROCESSING EQUIPMENT

(71) Applicant: APPLIED MATERIALS, INC., Santa Clara, CA (US)

(72) Inventors: Vahid FIROUZDOR, San Mateo, CA (US); Roberto COTLEAR, Sunnyvale, CA (US); Michael NICHOLS, Sunnyvale, CA (US); Imad YOUSIF, San Jose, CA (US); Steven E. BABAYAN, Los Altos, CA (US); Rajinder DHINDSA, Pleasanton, CA (US); Changhun LEE, San Jose, CA (US)

(21) Appl. No.: 15/784,846

(22) Filed: Oct. 16, 2017

Related U.S. Application Data
(60) Provisional application No. 62/414,173, filed on Oct. 28, 2016.

(51) Int. Cl. H01L 21/67; B01D 39/20; B01D 46/24; B01D 46/10

(52) U.S. Cl. CPC H01L 21/67069; B01D 39/2027; B01D 46/2403; B01D 2275/202; B01D 2239/1258; B01D 2279/51; B01D 46/10

(57) ABSTRACT

Methods and apparatus for delivering one or more gases to a process chamber are provided herein. In some embodiments a gas delivery system includes a process chamber having an inner volume; a gas source panel; a gas line coupling the inner volume to the gas source panel; and a first gas filter disposed along the gas line proximate the inner volume, wherein the first gas filter comprises a filter element body having a first end and a second end opposite the first end, and a filtration efficiency of about 1 to about 5 log reduction value (LRV).

### CROSS-REFERENCE TO RELATED APPLICATIONS

This application claims benefit of U.S. provisional patent application Ser. No. 62/414,173, filed Oct. 28, 2016, which is herein incorporated by reference in its entirety.

### FIELD

Embodiments of the present disclosure generally relate to substrate processing equipment.

### BACKGROUND

Within substrate processing equipment, for example in semiconductor substrate processing, some manufacturing processes may generate particles which frequently contaminate the substrate being processed, contributing to device defects. As device geometries shrink, susceptibility to defects increases and particle contaminant requirements become more stringent. The inventors have observed that contaminant particles can come from corrosion of the gas lines coupled to the processing equipment, for example due to corrosive gases that may be part of a particular substrate processing recipe.

Therefore, the inventors have provided improved methods and apparatus for reducing contaminants from gas lines in substrate processing equipment.

### SUMMARY

Methods and apparatus for delivering one or more gases to a process chamber are provided herein. In some embodiments a gas delivery system includes a process chamber having an inner volume; a gas source panel; a gas line coupling the inner volume to the gas source panel; and a first gas filter disposed along the gas line proximate the inner volume, wherein the first gas filter comprises a filter element body having a first end and a second end opposite the first end, and a filtration efficiency of about 1 to about 5 log reduction value (LRV).

In some embodiments, a substrate processing apparatus includes: a process chamber comprising a chamber body having sidewalls, a bottom, and a chamber lid that together define an inner volume of the process chamber; one or more gas inlet ports disposed through the chamber body and fluidly coupled to the inner volume; a substrate support disposed within the inner volume; and one or more first gas filters having a filtration efficiency of about 1 to about 5 LRV coupled to the inner volume at a location proximate to the process chamber.

In some embodiments, a method for delivering a gas into a process chamber includes: flowing a gas through a gas line from a gas panel having a gas panel filter to an inner volume of a process chamber; and flowing the gas through a first gas filter disposed downstream of the gas panel filter and proximate the inner volume of the process chamber, wherein the first gas filter has a filtration efficiency of about 1 to about 5 LRV.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 depicts a schematic view of a gas delivery system having gas filters in accordance with at least some embodiments of the present disclosure.

FIG. 2 is an isometric view of an exemplary gas filter in accordance with at least some embodiments of the present disclosure.

FIG. 3 depicts a sectional view of a gas filter illustratively disposed in a gas hub in accordance with at least some embodiments of the present disclosure.

FIG. 4 depicts a cross-sectional side view of a gas filter illustratively disposed in a gas line in accordance with at least some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Methods and apparatus for improved substrate processing equipment are provided herein. Embodiments of the present disclosure provide improved filtering of process gas contaminant particles that can be found in the supply gas lines of substrate processing equipment. For example, for semiconductor applications, such as etching processes, corrosive agents (such as comprising chlorine gas) are often used. The gas line systems are typically made out of low cost 312L stainless steel material. Stainless steel material usually has good corrosion resistance against chlorine gases, however, during chamber maintenance the gas lines are exposed to atmosphere. The moisture from the ambient and the residual chlorine gas adsorbed to the gas line surface react with each other and form hypochlorous acid (HClO), an oxidizing corrosive media which condenses on the internal surfaces of the gas line. HClO is severely corrosive and results in pitting corrosion of the gas line especially in the regions close to grain boundaries and localize carbides. The aforementioned corrosion issue results in the formation of corrosion by-products in the form of small particles. During process chamber operation, these particles will be carried to the chamber and cause substrate particle defects and metal contamination. The inventors have observed that particles with signatures of oxides of iron, for example, iron oxide, iron chromium oxide, and iron nickel oxide may be found on substrates, especially immediately following maintenance of stainless steel gas lines. The inventors have also observed that the same type of corrosion can also occur on other gas delivery system components such as valves, pressure gages, gas valve diaphragm, and the like, whether made of stainless steel or materials other than stainless steel. The inventors have discovered that the gas filter of the present disclosure may advantageously reduce the amount of contaminant particles that reach substrates. The gas filters can inserted to the locations similar to but not limited to gas line endpoint, gas hub, showerhead gas inlet, or the like.

In addition to contaminants from corrosion of the gas line, other sources of contamination may be advantageously addressed by the present disclosure. The inventors have discovered that substrates may also be contaminated by particles accumulated inside the gas lines due to erosion of o-rings and/or backstream condensation of process gases during or after previously performed substrate processing. For example, the inventors have observed that aluminum oxide based nanoparticles may form inside a gas line of an etch tool due to condensation of back streamed process chemistry gases.

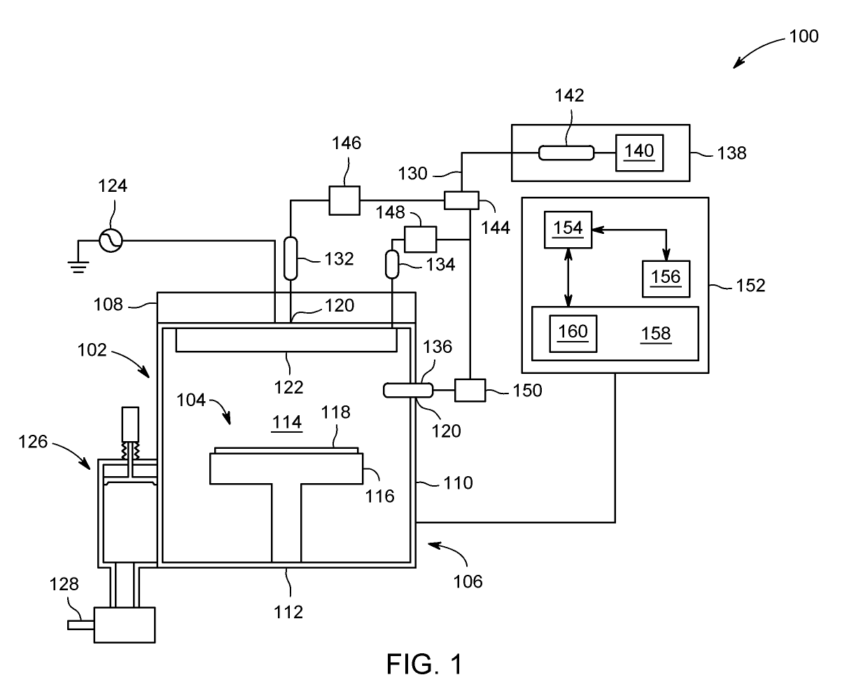

FIG. 1 is a schematic diagram of an exemplary gas delivery system 100 coupled to a process chamber and incorporating a gas filter in accordance with at least some embodiments of the present disclosure. Examples of suitable processing systems that may be suitably modified in accordance with the teachings provided herein include the ENDURA®, CENTURA®, and PRODUCER® processing systems or other suitable processing systems commercially available from Applied Materials, Inc., located in Santa Clara, Calif. Other processing systems (including those from other manufacturers) may be also adapted to benefit from the present disclosure.

The gas delivery system 100 may be coupled to a process chamber 102, for example, having an inner volume 104 surrounded by chamber body 106. In the exemplary embodiment depicted in FIG. 1, the chamber body 106 is defined by a chamber lid 108, sidewalls 110, and a bottom 112. The inner volume 104 may include a processing volume 114. The processing volume 114 may be defined, for example, between a substrate support 116 disposed within the process chamber 102 to support a substrate 118 during processing and one or more gas inlets 120. The one or more gas inlets 120 are provided to deliver gases into the processing volume 114 or other region of the inner volume 104. As depicted in the exemplary embodiment depicted in FIG. 1, the one or more gas inlets 120 may be located proximate the chamber lid 108, for example, through a showerhead or other gas distribution component (showerhead 122 shown), or through one or more locations on the sidewalls 110. Alternatively, or in combination, the one or more gas inlets 120 may be disposed through one or more locations on the bottom 112 or at other locations within the inner volume 104 (such as proximate or within the substrate support 116).

In some embodiments, the showerhead 122 may be configured to function as an RF electrode. As shown in FIG. 1, the showerhead 122 is coupled to RF power source 124. Optionally, other RF electrodes and RF power sources may be provided.

An exhaust system 126 comprising an exhaust port 128 for passing exhaust gases out of the inner volume 104 is coupled to the process chamber 102.

The gas delivery system 100 includes a gas line 130 provided to flow and deliver gases into the inner volume 104 of the process chamber 102. One or more first gas filters (e.g., first gas filters 132, 134, and 136 shown) are coupled to the gas line 130 proximate respective endpoints of the gas line 130, for example, adjacent the inner volume 104. In some embodiments, the first gas filter may be disposed in a gas line downstream of all gas sources and flow control devices (such as mass flow controllers, flow ratio controllers, valves, fixed orifices, or the like) in the gas line such that no flow control component (other than the terminal portion of the gas line) is disposed between the first gas filter and the chamber component to which the gas line is coupled, such as a showerhead, gas distribution hub, gas nozzle, or the like. In some embodiments, the first gas filter may be incorporated into the chamber component that delivers the gas to the inner volume 104 (e.g., the showerhead, gad distribution hub, gas nozzle, or the like). In some embodiments, the first gas filter may be disposed in a gas line downstream of all gas sources and flow control devices other than a shutoff valve disposed just upstream of the terminal portion of the gas line.

In some embodiments, the first gas filters (e.g., first gas filters 132,134, 136) may be fluidly coupled to the inner volume 104 via one or more components of the process chamber 102. For example, as depicted in the exemplary embodiment of FIG. 1, the first gas filters 132 and 134 are disposed atop the chamber lid 108 in respective locations relating to zones or sections of the showerhead 122 (such as an inner zone and an outer zone). The first gas filter 132 is coupled to an endpoint of the gas line 130 located in an exemplary location directed to a central section, or inner zone, of the showerhead 122. The first gas filter 134 is coupled to an endpoint of the gas line 130 located in the exemplary location directed to a peripheral section, or outer zone, of the showerhead 122. Although a two-zone showerhead is illustratively shown in FIG. 1, the gas line filter can be used in a single-zone showerhead, showerheads with more than two zones, or in chambers with no showerheads (e.g., coupled to other components as described herein).

In some embodiments, the first gas filters (e.g., first gas filters 132, 134, 136) may be disposed through the chamber body 106 (or provided in other locations). For example, as illustrated in FIG. 1, the first gas filter 136 is disposed through the sidewall 110 and directly coupled to the inner volume 104. First gas filters may also be provided in other locations wherever a gas is provided to the inner volume 104.

The gas delivery system 100 further includes a gas panel 138 coupled to the inner volume 104 by the gas line 130. The gas panel 138 comprises one or more gas sources (gas source 140 shown) containing one or more gases for use in processes within the inner volume 104. In some embodiments, the gas panel 138 may include a second gas filter 142. The second gas filter 142 may have a filtration efficiency of at least about 9 log reduction value (LRV) (out of 1×10⁹ particles >20 nm, one will pass through the filter). The second gas filter 142, located in a relatively high pressure area of the gas delivery system 100 (e.g., near the gas source 140), can use a high efficiency filter such as a 9 LRV gas filter suitable for removing particles in the gas provided by the gas source 140.

In some embodiments, the gas delivery system 100 includes a flow splitter 144 to apportion gases from the gas panel 138 to various endpoints of the gas line 130 disposed in respective process chamber locations. For example, as depicted in FIG. 1, the flow splitter 144 may redirect part of the gas flow toward a first zone of the showerhead 122 and another part toward a second zone of the showerhead and/or to the one or more gas inlets 120 disposed on the sidewalls 110 or elsewhere in the process chamber. The flow splitter 144, or other flow splitters (not shown), can be used to divide the flow as desired into multiple streams as appropriate for delivering the gas to the inner volume 144 as desired for a particular application. The flow splitter 144 is located downstream of the gas panel 138 and upstream of the first gas filters 132, 134, 136. In some embodiments, one or more gas flow control elements may be used to control the flow of gases along the gas line 130, for example, gas flow control elements 146, 148, 150 disposed between the flow splitter 144 and the respective first gas filters 132, 134, 136. In some embodiments, the gas flow control elements 146, 148, and 150 may be mass flow controllers (MFCs) or the like.

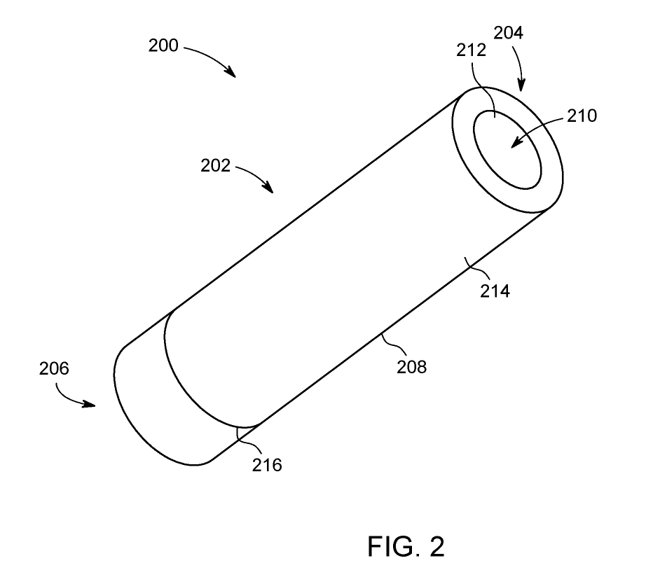

FIG. 2 shows an isometric view of a gas filter 200, such as the exemplary first gas filters 132, 134,136 of FIG. 1. The gas filter 200 comprises a filter element body 202. The filter element body 202 has a first end 204 and a second end 206, opposite the first end 204. The filter element body 202 has a filtration efficiency of about 1 to about 5 LRV, or in some embodiments, about 2 to about 4 LRV. By providing a lower filtration efficiency (as compared to the typical 9 LRV filtration efficiency for gas filters used in high pressure regions proximate the gas source), such gas filters can advantageously be used further downstream in lower pressure regions closer to the process chamber where higher efficiency filters could not be used satisfactorily. Specifically, use of a high efficiency filter would undesirably cause a significant reduction in pressure and slow down the gas flow toward the process chamber. The effect of such a pressure drop and delay is significantly more in lower pressure locations (e.g., downstream of a mass flow controller, flow ratio controller, flow control valve, fixed orifice, etc.) and as a result, high efficiency gas filters are not used in the lower pressure regions. In addition, although more particles will have the chance to pass through the gas filter (because the porosity matrix of the gas filter is more open compared to traditional gas filters), the filtration performance of 1-5 LRV (from 10-100,000 particle only one will pass the filter) provided by the gas filter still provides a huge improvement in defect performance of a semiconductor chamber. Such improvement in defect performance (i.e., reduction in defects) is advantageous for many processes, in particular for sensitive applications, such as logic device fabrication or the like.

The filter element body 202 comprises one or more materials having corrosion resistance to commonly used process gases, for example Cl₂, O₂, SiCl₄, NF₃, NH₄, CH₂, and others. In some embodiments, the filter element body 202 may be made from stainless steel (such as 316L SST), nickel, or nickel-based alloys (such as an alloy comprising nickel, chromium, iron, molybdenum, cobalt, and tungsten, for example HASTELLOY®, commercially available from Haynes International, located Kokomo, Ind.), or the like. The filter is made with partially sintered powder of the above materials having a porosity permeable for process gases but not for large enough particles. The sintered filter material has a larger porosity matrix, as compared to conventional gas filters, advantageously providing significantly less pressure drop and delay. Hence, the gas filter can be used in low pressure regions unlike traditional gas filters. The gas filter can also be made in small cylindrical or disk shapes which can advantageously be easily installed at the ends of gas lines or gas hubs with no major design changes.

In some embodiments, for example, in the non-limiting exemplary embodiment depicted in FIG. 2, the filter element body 202 may be tubular. The cylindrical filter element body 202 further comprises a midsection 208. A first opening 210 is disposed through first end 204 to form an inner surface 212 along the interior of the midsection 208 and an outer surface 214 along the exterior of the midsection 208. The first opening 210 terminates proximate the second end 206. In some embodiments, the second end 206 of the filter element body 202 is closed and fabricated from the same material, having the same porosity, as the remainder of the filter element body 202. In some embodiments, an endcap 216 may be disposed at the second end 206. In some embodiments, the endcap 216 is solid such that gas cannot flow through the endcap 216.

In some embodiments, the inner diameter of the midsection 208 may be about 0.125 inches to about 2.00 inches, or in some embodiments, about 0.125 inches to about 0.25 inches. In some embodiments, the outer diameter of the midsection 208 may be about 0.125 inches to about 1 inch. In some embodiments, the length of the midsection 208 may be in a range from about 0.50 inches to about 10 inches. In some embodiments, the surface area of the inner surface 212 may be, for example, between about 0.2 square inches and about 63 square inches. Other dimensions having other surface areas may also be used in certain applications depending upon the gas flow characteristics required.

Returning to FIG. 1, if the diameter of the gas line is too small to accommodate the gas filter, in some embodiments, the end of the gas line 130 proximate the process chamber may include an expanded section to accommodate the first gas filter. Specifically, the expanded section allows insertion of a first gas filter (e.g., first gas filter 132) having an outer diameter larger than the inner diameter of the gas line, without significantly altering the form or increasing the cost of the gas delivery system. For example, the inner diameter of a section of the gas line 130 extending upstream from the endpoint of the gas line 130 may be enlarged, for example, from about 0.25 inches to about 0.5 inches (or other suitable dimension to accommodate the first gas filter). For example, a transition weldment may be provided to expand the inner diameter of the of the end section and provide a fit with a first gas filter 132 having an outer diameter of the midsection 208 larger than a diameter of the gas line 130.

The length of the first gas filter may vary depending on the total flow passing through the gas line 130. In some embodiments, the length of the first gas filter may be about 0.5 inches to about 8 inches. In addition, the length, diameter, or other configuration of each first gas filter may vary depending upon the location of use. For example, in some processing systems first gas filters provided in some gas delivery locations or zones may be longer than other first gas filters provided in other gas delivery locations or zones. For example, zones that receive more of the total gas flow may use longer first gas filters than zones that receive less of the total gas flow.

In some embodiments, the filter element body 202 may be in the form of a disc rather than a tube. A disc shaped filter may be advantageous, for example, with gas line endpoints having substantially larger cross sectional areas.

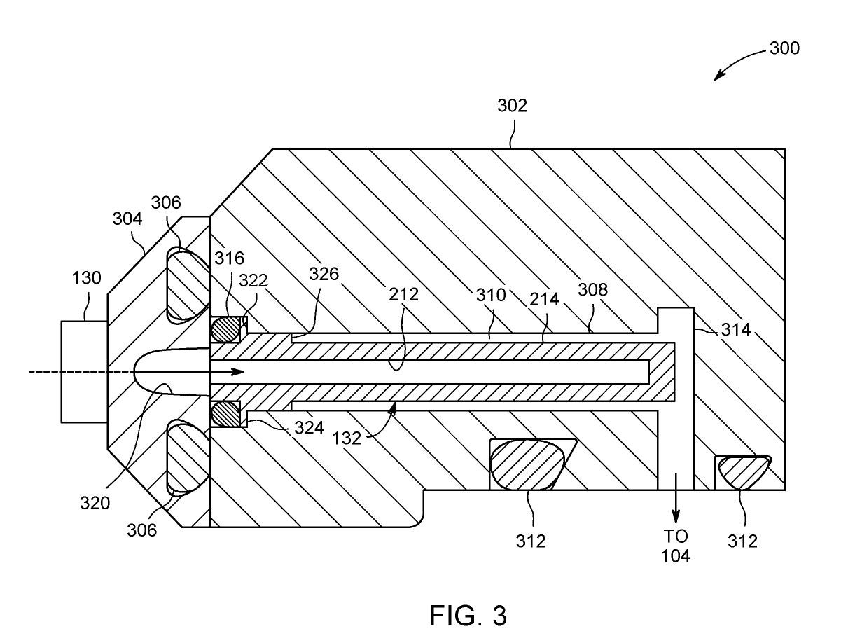

FIG. 3 depicts a sectional view of a first gas filter illustratively disposed in a gas hub in accordance with at least some embodiments of the present disclosure. The gas hub facilitates local distribution of gas from the gas line 130 to one or more zones within the process chamber. In some embodiments, the hub may be coupled to or otherwise disposed proximate the lid of the process chamber. As depicted in FIG. 3, a gas hub 300 includes a hub body 302 having the first gas filter 132 installed in the hub body 302. The hub body 302 advantageously couples the first gas filter 132 to the end of the gas line 130 and routes filtered gases into the inner volume 104, for example into the processing volume 114 depicted in FIG. 1. The location of installation in the side of the gas hub 300 provides easy access to the first gas filter 132, for example for routine maintenance or replacement. In some embodiments the hub body 302 may be made of ceramic or other suitable process-compatible material.

In some embodiments, the gas hub 300 may be disposed atop the chamber lid 108 (depicted in FIG. 1), and immediately above the showerhead 122. One or more seals 312 (similar to seals 306) may be provided to prevent or minimize gas leaks along the interface of the gas hub 300 and the chamber lid 108.

The hub body 302 is connected to the endpoint of the gas line 130 proximate the process chamber 102. A collar 304 having one or more seals 306 (for example, a gasket, o-ring, or the like) attaches the hub body 302 to the endpoint of the gas line 130 while preventing or limiting any gas leaks at the interface of the gas line 130 and the gas hub 300. An opening 320 in the collar 304 fluidly couples the first gas filter 132 to the gas line 130.

The hub body 302 includes a passageway 308 having a diameter greater than the diameter of the first gas filter 132 to define a gap 310 between the outer surface 214 of the first gas filter 132 and the surface of the hub body 302 along the passageway 308. The gap 310 is provided to facilitate passing filtered gas from the first gas filter 132 into the inner volume 104 depicted in FIG. 1.

In some embodiments, the passageway 308 may include a counterbore formed at the outer surface of the hub body 302 defining a shoulder 322 near the end of the passageway 308. The first gas filter 132 may include a flange 324 proximate the end of the first gas filter 132 to rest on the shoulder 322 when installed and to facilitate proper placement of the first gas filter 132 in the hub body 302. A seal 316 (similar to seals 306, 312) may be provided around the end of the first gas filter 132 and adjacent to the flange 324. The seal 316 sits in a space defined by the outer diameter of the end of the first gas filter 132, the flange 324, an inner surface of the counterbore, and the adjacent surface of the collar 304 and prevents or limits any gas from bypassing the first gas filter 132 when flowing into the passageway 308. A portion 326 of the first gas filter 132 adjacent to the flange 324 may be provided with an enlarged diameter slightly smaller than the diameter of the passageway 308 to facilitate positioning and holding the first gas filter 132 in place within the passage. The enlarged diameter portion 326 of the first gas filter 132 may also further minimize risk of gas bypassing the first gas filter 132.

A conduit 314 having a passage volume 318 couples the passageway 308 (and gap 310) to the inner volume 104, for example through the showerhead 122, as illustrated by the directional arrow pointing in the direction of the inner volume 104. Although not shown, the chamber lid 108 of the process chamber may have additional conduits as needed to control the flow of gas to desired locations within the process chamber.

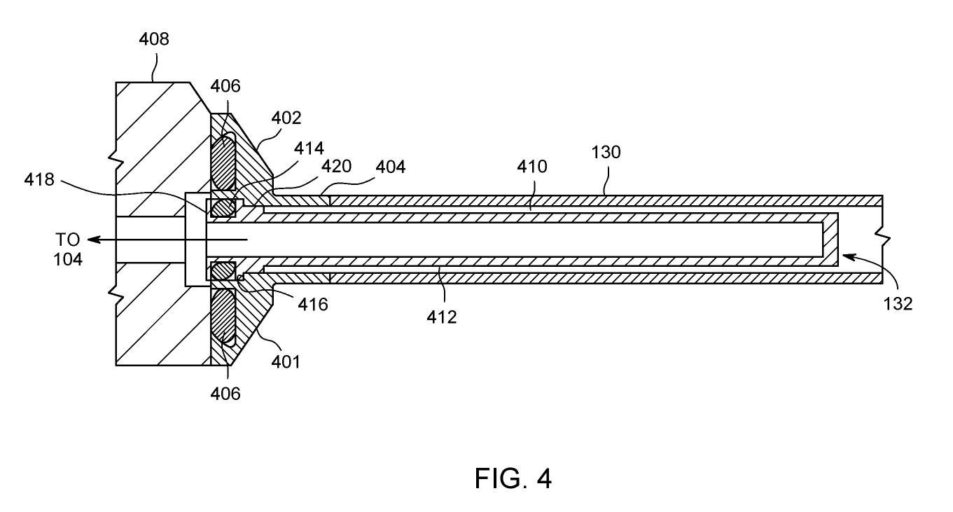

FIG. 4 depicts a sectional view of the details of a gas line 130 with an elongated flange 401 having the exemplary first gas filter 132 disposed therein. The elongated flange 401 comprises a flange section 402 and a stem 404 extending from the flange section 402. The stem 404 is coupled in-line to the gas line 130. The flange section 402 and the stem 404 are hollow and continue the gas passage of the gas line 130. In some embodiments, the elongated flange 401 may be made of the same material as the gas line 130 or other suitable material.

The stem 404 (and inner surface of the gas line 130) and an outer surface 412 of the first gas filter 132 define a gap 410 surrounding the outer surface 412. The gap 410 is provided to facilitate flow of gas through the first gas filter 132. Although FIG. 4 is described with the gas flowing in one direction, the direction of flow could also be reversed.

The flange section 402 of the elongated flange 401 is coupled to a gas distribution component 408 of the process chamber, for example by bolting or clamping. The gas distribution component 408 may be part of a gas hub, showerhead, or other component coupled to the end of gas line 130 proximate the process chamber. The flange section 402 includes a seal 406 (similar to seals 306, 312, 316 discussed above) to prevent or limit gas leaks at the interface between the flange section 402 and the gas distribution component 408.

In some embodiments, the flange section 402 may include a counterbore formed at the end of the flange section 402 defining a shoulder 416 near the end of the flange section 402. The first gas filter 132 may include a flange 418 proximate the end of the first gas filter 132 to rest on the shoulder 416 when installed and to facilitate proper placement of the first gas filter 132 in the flange section 402. A seal 414 (similar to seals 306, 312, 316, and 406) may be provided around the end of the first gas filter 132 within a groove formed in the outer diameter of the flange 418. The seal 414 sits in a space defined by the groove in the flange 418 and an inner surface of the counterbore and prevents or limits any gas from bypassing the first gas filter 132. A portion 420 of the first gas filter 132 adjacent to the flange 418 may be provided with an enlarged diameter slightly smaller than the inner diameter of the elongated flange 401 to facilitate positioning and holding the first gas filter 132 in place within the passage. The enlarged diameter portion 420 of the first gas filter 132 may also further minimize risk of gas bypassing the first gas filter 132.

In operation, as illustrated in FIG. 1, one or more gases flow from the gas source 140 in the gas panel 138. Prior to or upon exiting the gas panel 138, the one or more gases flow through the second gas filter 142 having a filtration efficiency of about 9 LRV. By definition, one out of one billion particles having a particle size of 20 nanometers or more will pass through the second gas filter 142. As the one or more gases flow through the gas line 130, the flow splitter 144 may selectively apportion and channel portions of gases or gas mixtures towards one or more endpoints of the gas line 130, disposed proximate the inner volume 104. In some embodiments, flow control elements, for example, gas flow control elements 146, 148, and 150 may be used to control the flow rate of the one or more gases departing from the flow splitter 144 towards various sections of the gas line 130 disposed at the respective endpoints of the gas line 130, proximate the inner volume 104.

However, the inventors have observed that as the one or more gases flow along the gas line 130, corrosion of the gas line 130 and the other flow components, for example, the flow splitter 144 or the gas flow control elements 146, 148, 150 may undesirably contaminate the one or more gases before they are delivered to the inner volume 104. The first gas filters 132, 134, 136 provided with a filtration efficiency of about 1 LRV to about 5 LRV, for example, about 2 LRV to about 4 LRV, are advantageously coupled to the gas line 130, proximate endpoints of the gas line 130 disposed proximate the inner volume 104. Thus, the first gas filters 132, 134, 136 perform a filtration of the one or more gases immediately prior to delivery of the gas into the inner volume 104.

In some embodiments, the first gas filters 132, 134, 136 may provide the same filtration efficiency to gases flowing in the gas line 130 and incident upon the inner surfaces 212 of the first gas filters 132, 134, 136 at a flow rate between about 10 sccm to about 10,000 sccm. In some embodiments according to the present disclosure, the first gas filters 132, 134, 136 may provide a similar filtration efficiency even when located in region of low pressure, for example, relative to the pressure inside the gas line 130 at an exit point of the gas panel 138. For example, the first gas filters 132, 134, 136 may be located in a portion of the gas line 130 proximate the inner volume having a pressure less than 500 mTorr, for example, between about 1 mTorr and 500 mTorr.

When provided as part of the gas delivery system 100, the first gas filter (e.g., 132, 134, or 136) further ensures a stable pressure difference in inside the gas line 130, between a first point located upstream of the first gas filter (e.g., 132, 134, or 136) and a second point located downstream of the first gas filter (e.g., 132, 134, or 136). For example, when using the exemplary first gas filter 132 having a filtration efficiency of about 1 LRV to about 5 LRV pressure build up in the gas line 130 which may otherwise occur due to filter induced gas flow blockage on the inner surface 212, is advantageously avoided, and a stable pressure difference between the inner surface 212 and the outer surface 214 is maintained. Accordingly, the first gas filter (e.g., 132, 134, or 136) allows for uninterrupted flow of the one or more gases, for example by delaying the flow by a negligible amount of time, for example, by less than 0.2 seconds.

A controller 152 may be provided and coupled to various components of the gas delivery system 100 to control the operation of the gas delivery system 100. The controller 152 includes a central processing unit (CPU) 154, support circuits 156 and a memory or computer readable medium 158, and support circuits 156. The controller 152 may control the gas delivery system 100 directly, or via computers (or controllers) associated with particular process chamber and/or support system components. The controller 152 may be any form of general-purpose computer processor that can be used in an industrial setting for controlling various chambers and sub-processors. The memory, or computer readable medium, 158 of the controller 152 may be one or more of readily available memory such as random access memory (RAM), read only memory (ROM), floppy disk, hard disk, optical storage media (e.g., compact disc or digital video disc), flash drive, or any other form of digital storage, local or remote. The support circuits 156 are coupled to the CPU 154 for supporting the processor in a conventional manner. These circuits include cache, power supplies, clock circuits, input/output circuitry and subsystems, and the like. Inventive methods as described herein, such as the method for providing one or more gases to a process chamber, may be stored in the memory 158 as software routine 160 that may be executed or invoked to control the operation of the gas delivery system 100 in the manner described herein. The software routine may also be stored and/or executed by a second CPU (not shown) that is remotely located from the hardware being controlled by the CPU 154.

Thus, improved gas filters and gas delivery systems incorporating such gas filters have been provided herein. The methods and systems disclosed herein provide process gas contaminant particle filtering that may advantageously be utilized in low pressure regions of a processing equipment supply gas line.

While the foregoing is directed to embodiments of the present disclosure, other and further embodiments of the disclosure may be devised without departing from the basic scope thereof.

1. A gas delivery system, comprising:
a process chamber having an inner volume;
a gas source panel;
a gas line coupling the inner volume to the gas source panel; and
a first gas filter disposed along the gas line proximate the inner volume, wherein the first gas filter comprises a filter element body having a first end and a second end opposite the first end, and a filtration efficiency of about 1 to about 5 log reduction value (LRV).

2. The gas delivery system of claim 1, wherein the first end of the first gas filter is attached to an endpoint of the gas line.

3. The gas delivery system of claim 2, wherein the first gas filter is housed in a gas hub.

4. The gas delivery system of claim 1, wherein the gas source panel further comprises a second gas filter having a filtration efficiency of about 9 LRV.

5. The gas delivery system of claim 4, wherein the gas line further comprises
a flow splitter located downstream of the second gas filter, and a plurality of first gas filters, located downstream of the flow splitter.

6. The gas delivery system of claim 1, wherein the first gas filter comprises a material having corrosion resistance to Cl₂, O₂, SiCl₄, NF₃, NH₄, and CH₂.

7. The gas delivery system of claim 1, wherein the filter element body is made of a metal alloy comprising nickel, chromium, iron, molybdenum, cobalt, and tungsten.

8. The gas delivery system of claim 1, wherein the filter element body is tubular and comprises a midsection having an inner surface and an outer surface.

9. The gas delivery system of claim 8, wherein the midsection has an inner diameter between about 0.125 inch and about 0.25 inch, and an outer diameter between about 0.125 inches and about 1 inch.

10. The gas delivery system of claim 9, wherein the midsection has a length between about 0.50 inch and about 10 inches.

11. The gas delivery system of claim 8, wherein the first gas filter is disposed within an endpoint of the gas line.

12. The gas delivery system of claim 1, wherein the filter element body is a disc.

13. A substrate processing apparatus, comprising:
a process chamber comprising a chamber body having sidewalls, a bottom, and a chamber lid that together define an inner volume of the process chamber;
one or more gas inlet ports disposed through the chamber body and fluidly coupled to the inner volume;
a substrate support disposed within the inner volume; and
one or more first gas filters having a filtration efficiency of about 1 to about 5 LRV coupled to the inner volume at a location proximate to the process chamber.

14. The substrate processing apparatus of claim 13, wherein one or more first gas filters are disposed adjacent to or in at least one of the sidewalls or the bottom.

15. The substrate processing apparatus of claim 13, wherein one or more first gas filters are disposed adjacent to or in the chamber lid.

16. The substrate processing apparatus of claim 13, wherein one or more filters are disposed in a showerhead disposed opposite the substrate support.

17. A gas delivery method, comprising:
flowing a gas through a gas line from a gas panel having a gas panel filter to an inner volume of a process chamber; and
flowing the gas through a first gas filter disposed downstream of the gas panel filter and proximate the inner volume of the process chamber, wherein the first gas filter has a filtration efficiency of about 1 to about 5 LRV.

18. The gas delivery method of claim 17, wherein the gas panel filter has a filtration efficiency of about at least 9 LRV.

19. The gas delivery method of claim 17, further comprising one or more of a mass flow controller, a flow ratio controller, a flow control valve, or a fixed flow control orifice disposed in the gas line downstream of the gas panel filter and upstream of the first gas filter.

20. The gas delivery method of claim 17, wherein the first gas filter is disposed immediately adjacent to a showerhead, gas distribution hub, or gas nozzle coupled to the process chamber.
